(19) United States
(12) Patent Application Publication
(10) Pub. No.: US 2010/0141955 A1
(43) Pub. Date: Jun. 10, 2010

(54) Sensor probe for fiber-based current sensor

(76) Inventor: Yong Huang, Milpitas, CA (US)

Correspondence Address: Yong Huang, 1079 Sandalwood LN, Milpitas, CA, 95035, US

(21) Appl. No.: 12/592,393

(22) Filed: Nov. 24, 2009

Related U.S. Application Data
(60) Provisional application No. 61/200,760, filed on Dec. 4, 2008.

(51) Int. Cl. G01B 9/02; G01R 3/00

(52) U.S. Cl. 356/483; 29/428; 29/595

(57) ABSTRACT

Embodiments of the present invention provide a sensor probe for fiber-based electric current sensors. The sensor probe includes a conductor of spiral shape and a relatively straight optical fiber being placed at a through-hole formed by the spiral shape conductor. An electric current conveyed by the spiral shape conductor causes polarization direction of a light traveling along the optical fiber to rotate. By detecting the amount of rotation that the light experiences at the ends of the optical fiber, the amount of current carried by the spiral shape conductor is determined. Method of making the sensor probe is also disclosed.

### CROSS REFERENCE TO RELATED APPLICATION

The present application claims benefit of priority of a U.S. provisional patent application Ser. No. 61/200,760 entitled “Sensor Probe for Fiber-Based Current Sensor”, filed Dec. 4, 2008 with the United States Patent and Trademark Office, the content of which is incorporated herein by reference in its entirety.

### FIELD OF THE INVENTION

The present invention relates to method and devices for sensing electric current, and in particular, relates to sensor probes used in fiber-based electric current sensor.

### BACKGROUND OF THE INVENTION

It is well known in the art that electric current, in particular large electric current ranging from tens up to several thousands amperes, may be detected and/or monitored by a fiber-based current sensor. As is known in the art, a fiber-based current sensor generally includes a probe head that is made of a straight conductor being wrapped around by a fiber coil or coils. When an electric current passes through the conductor, the electric current may produce a magnetic field around the conductor, in particular at locations where the fiber coil is situated. According to well-known Faraday's effect, this magnetic field may cause polarization direction of a light that propagates inside and along the fiber coil to rotate. The current sensor may additionally include other optical signal (light) detecting and processing devices. By measuring the degree of rotation of polarization direction of the light caused by the magnetic field using the current sensor, the amount of electric current conveyed by the conductor may be determined.

In the above fiber-based current sensor, the sensing optical fiber is wrapped around the straight current-carrying conductor. Thus, performance of the current sensor may be affected by potential variations in birefringence and/or stresses of the fiber, which may be caused by change in environment and/or due to aging effect.

### SUMMARY OF EMBODIMENTS OF THE INVENTION

Embodiments of the present invention provide a current sensor probe that includes a relatively straight optical fiber and a spiral shape conductor surrounding the optical fiber. The spiral shape conductor is machined or casted to have at least one coil, preferably between two (2) and four (4) coils, that form a through-hole in a center thereof wherein the optical fiber is placed.

In one embodiment,.a sensor probe for sensing electric current is provided. The sensor probe includes an optical fiber; and a spiral shape conductor having at least one coil and a through-hole in a center of the spiral shape conductor formed by the coil, wherein the optical fiber is placed inside and along the through-hole of the spiral shape conductor.

In another embodiment, the sensor probe further includes a protective tube being placed inside the through-hole of the spiral shape conductor, wherein the optical fiber is placed inside the protective tube, thereby being protected by the protective tube.

In one embodiment, the spiral shape conductor has a first and a second terminal providing a conductive path from the first terminal to the second terminal for an electric current, and wherein an optical signal propagating inside the optical fiber is adapted to detect the electric current conveyed by the spiral shape conductor. The first and second terminals have a diameter of at least 50 mm and cross-sections of the first and second terminals are sufficiently large to support conveying a current between about 1500 A and 3500 A.

According to one embodiment, a quarter-wave plate is connected in series inside the optical fiber at a first side of the spiral shape conductor, and the optical fiber is terminated by a reflective mirror at a second side of the spiral shape conductor. According to another embodiment, a quarter-wave plate is connected in series inside the optical fiber at a first side of the spiral shape conductor, wherein the optical fiber is rounded back from a second side of the spiral shape conductor, via outside thereof, to the first side of the spiral shape conductor and is terminated by a reflective mirror at a location substantially close to the quarter-wave plate. According to yet another embodiment, a first and a second quarter-wave plate are connected in series inside the optical fiber at a first side and a second side of the spiral shape conductor.

Embodiments of the present invention also provide a method of detecting electric current. The method includes steps of launching an optical signal into an optical fiber, the optical fiber having a relatively straight section being placed inside a through-hole of a spiral shape conductor; conveying an electric current through the spiral shape conductor; detecting a rotation of polarization direction of the optical signal; and determining an amount of the electric current from the rotation of polarization direction.

Embodiments of the present invention further provide a method of making sensor probe for fiber-based electric current sensor. For example, the method includes steps of providing a bulky cylindrical conductor; machining a through-hole at a center of the cylindrical conductor; machining the cylindrical conductor into a spiral shape, with the spiral shape surrounding the through-hole; and positioning an optical fiber substantially straight inside the through-hole.

### BRIEF DESCRIPTION OF THE DRAWINGS

The present invention will be understood and appreciated more fully from the following detailed description of embodiments of the invention, taken in conjunction with accompanying drawings of which:

FIG. 1A and FIG. 1B are demonstrative illustrations of sensor probes generally used in a conventional fiber-based current sensor;

FIG. 2 is a demonstrative illustration of a sensor probe that may be used in a fiber-based current sensor, according to one embodiment of the present invention;

FIG. 3 is a demonstrative illustration of a sensor probe that may be used in a fiber-based current sensor, according to another embodiment of the present invention;

FIG. 4 is a demonstrative illustration of a sensor probe that may be used in a fiber-based current sensor, according to yet another embodiment of the present invention;

FIG. 5 is a demonstrative illustration of a method of manufacturing a sensor probe according to one embodiment of the present invention;

FIG. 6 is a demonstrative illustration of a method of manufacturing a sensor probe according to another embodiment of the present invention;

FIG. 7 is a demonstrative illustration of a method of manufacturing a sensor probe according to yet another embodiment of the present invention;

FIG. 8 is a picture of a prototype sensor probe made in accordance with an embodiment of the present invention, before a sensing fiber is installed in a center hole; and

FIG. 9 is a demonstrative illustration of a cross-sectional view of a sensor probe made in accordance with an embodiment of the present invention.

It will be appreciated that for the purpose of simplicity and clarity of illustration, elements in the drawings have not necessarily been drawn to scale. For example, dimensions of some of the elements may be exaggerated relative to other elements for clarity purpose.

### DETAILED DESCRIPTION OF EMBODIMENTS OF THE PRESENT INVENTION

Embodiments of the present invention provide a sensor probe designed for fiber-based current sensors. The sensor probe, which may sometimes be referred to hereinafter as “probe head” or “sensor probe head”, may include a conductor of spiral shape and an optical fiber being placed or situated through a center hole formed by the spiral shape conductor. An electric current going through the spiral shape conductor may cause polarization direction of a light that propagates along the optical fiber to rotate. By detecting the amount of rotation that the light experiences during propagation between the two ends of the optical fiber, the amount of current carried or conveyed by the conductor may be determined. Comparing with conventional types of fiber-based current sensors that use a fiber coil around a straight conductor that carries current, the use of a straight optical fiber in the center of a spiral shape current-carrying conductor may significantly reduce the influence of changes of birefringence of fiber on the state of light and thus improves the long-term stability of the current sensor.

Generally, according to well-known Faraday's effect, electric current carried by a conductor placed at the center of a fiber coil may cause polarization state of light propagating inside the fiber coil to rotate. Similarly, electric current carried by a spiral shape conductor wrapped around a straight optical fiber may cause polarization state of light inside the straight optical fiber to rotate. By detecting the amount of rotation of the light, the amount of current carried by the spiral shape conductor may be determined.

The present invention provides a sensor probe, and method of making the same, having a spiral shape conductor being wrapped around a relatively straight optical fiber. Although the fiber may not need to be straight, when being compared with a fiber coil, a relatively straight optical fiber will experience less performance degradation and/or variation that are normally associated with, for example, birefringence and/or stress of the fiber. An electric current flowing along and being conveyed by the spiral shape conductor may cause polarization state of the light propagating inside the fiber, which is placed along a center hole formed by the spiral shape conductor, to rotate. Therefore, the spiral shape conductor, together with the relatively straight optical fiber, may be used as a probe head, or a sensor probe, for a fiber-based current sensor.

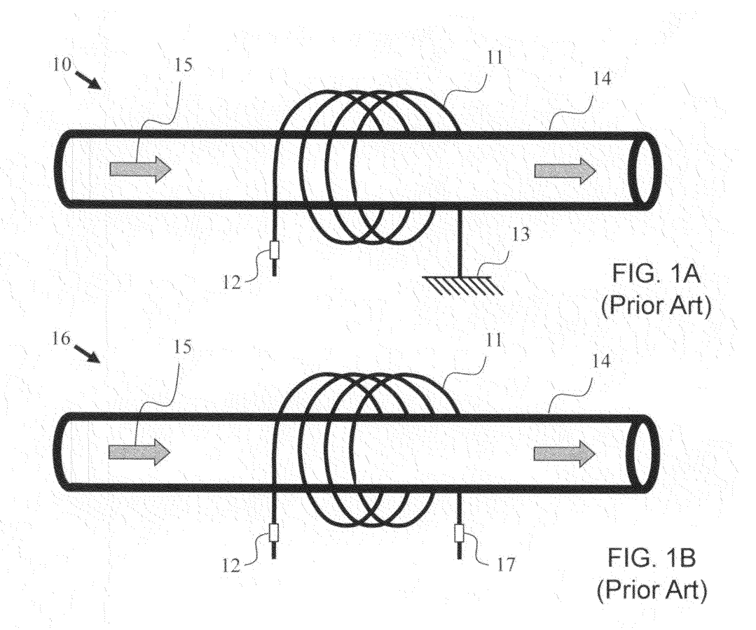

FIG. 1A is a demonstrative illustration of a sensor probe used in a typical fiber-based current sensor. For example, in FIG. 1A, sensor probe 10 is a reflective-type probe and include an optical fiber 11 being wrapped around a straight conductor 14. In other words, optical fiber 11 is a fiber coil 11. One port of optical fiber 11 may be terminated, polished and/or optically treated, to have the effect of a reflective mirror 13 and the other port may be connected to a quarter-wave plate 12. An electric current 15 going through conductor 14 may cause polarization direction of a light propagating inside optical fiber 11 to rotate. The amount of polarization rotation may be detected at the input/output port of fiber 11, via quarter-wave plate 12, and the information may be used to determine the amount of current being carried by conductor 14. Further reference may be made to US Patent Publication S/N: 20080310791, for more details of operation of a fiber-based current sensor, which in incorporated herein by reference in its entirety.

FIG. 1B is a demonstrative illustration of another sensor probe used in a typical fiber-based current sensor. In FIG. 1B, sensor probe 16 is a through-type probe with optical fiber 11 being wrapped around conductor 14. Here, instead of using a reflective mirror 13, optical fiber 11 has a first and a second input/output port. The first port of optical fiber 11 is connected to quarter-wave plate 12 and the second port of optical fiber 11 is connected to a quarter-wave plate 17. An optical signal, being launched into for example the first port of optical fiber 11 via quarter-wave plate 12, may experience rotation of polarization direction and subsequently exit the second port of optical fiber 11 via quarter-wave plate 17. A difference in polarization direction between the first (input) and second (output) ports of optical fiber 11 may be detected and used to determine the amount of electric current 15 being carried by conductor 14.

As being discussed above, an optical signal propagating inside fiber coil 11 used in the above conventional sensor probes, as shown in FIGS. 1A and 1B, may be sensitive to variation in birefringence and/or to stresses of fiber coil 11, thereby causing performance variation and/or degradation of any current sensor using sensor probes 10 and 16.

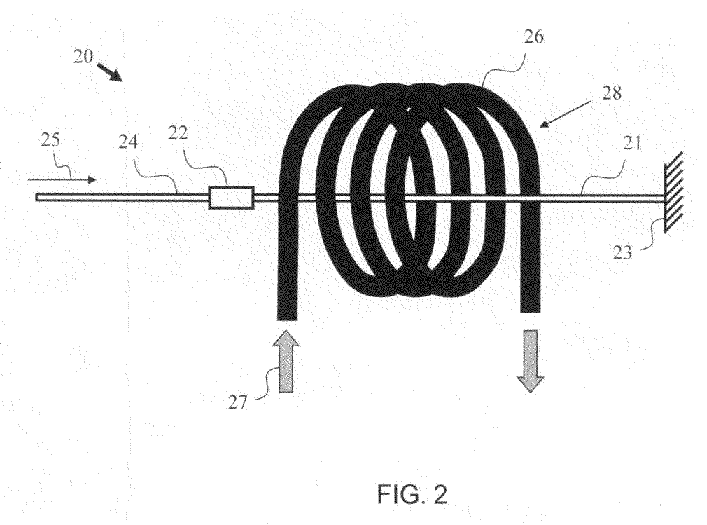

FIG. 2 is a demonstrative illustration of a sensor probe that may be used in a fiber-based current sensor according to one embodiment of the present invention. Sensor probe 20 may be a reflective-type sensor probe, and may include an optical fiber 21 and a spiral shape conductor 26 being formed to surround optical fiber 21 with at least one coil, preferably between two (2) and four (4) coils. Optical fiber 21, which may sometimes be referred to hereinafter as a sensing fiber, may have one end being connected to a reflective mirror 23 or may be optically treated with a reflective coating to have the effect of an optical mirror. The other end of optical fiber 21 may be connected to an input/output fiber 24 through a quarter-wave plate 22. In one embodiment, fibers 21 and 24 may be considered as one single fiber, and in this case quarter-wave plate 22 may be considered as being connected inside fiber 21/24 in series.

Spiral shape conductor 26 may convey an electric current 27. Electric current 27 may be a large current, for example larger than 10A (ampere) and typically around 2500 A. In one embodiment electric current 27 supported by spiral shape conductor 26 maybe between 100 A to 4000 A, preferably between 1500 A and 3500 A, and more preferably between 2000 A and 3000 A like those commonly found in a power grid of electric power transportation. However, embodiments of the present invention are not limited in the above aspect, and smaller or larger current may be carried by spiral shape conductor 26. For example, in one embodiment, spiral shape conductor 26 may be able to support a transient electric current 27 as big as 20000 A, which may last for a short period of time of for example one (1) to five (5) seconds. Spiral shape conductor 26 may be able to support the above large electric current without generating substantial heat that may affect the performance of the sensor probe 20.

During operation, an optical signal 25 may be launched into sensing fiber 21 through input/output fiber 24 via quarter-wave plate 22. While propagating along fiber 21 inside a center hole (through-hole) 28 formed by spiral shape conductor 26, optical signal 25 may experience rotation of polarization direction, both in the forward and in the backward direction after being reflected back by mirror 23, caused by the large current 27 conveying inside conductor 26. The amount of polarization rotation may be detected and information carried by the rotated polarized light being processed to determine the amount of current being carried by conductor 26.

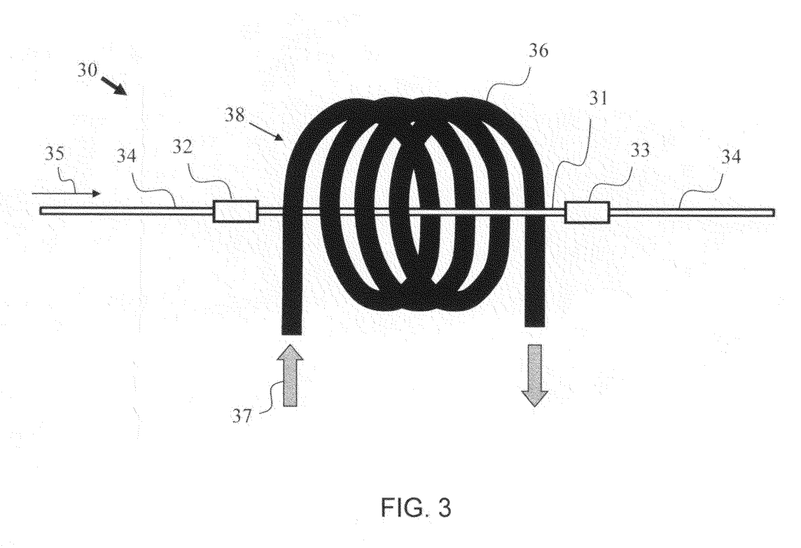

FIG. 3 is a demonstrative illustration of a sensor probe that may be used in a fiber-based current sensor according to another embodiment of the present invention. For example, sensor probe 30 may be a through-type probe and may include a sensing fiber 31 being placed inside a center hole (through-hole) 38 of a spiral shape conductor 36 that has at least one coil (preferably 2-4 coils). The two ends of sensing fiber 31, at the outside of center hole 38, may be connected to an input/output fiber 34 through quarter-wave plate 32 and quarter-wave plate 33, respectively. An electric current 37 conveyed by spiral shape conductor 36 may create a magnetic field in places where sensing fiber 31 is placed or situated, and thus may cause polarization direction of an optical light 35, being launched into fiber 31 via quarter-wave plate 32, to rotate while propagating along sensing fiber 31 inside center hole 38. Optical light 35 may eventually exit optical fiber 31 via quarter-wave plate 33 and a difference in polarization direction at the two ends of optical fiber 31 may be detected. The information in difference of polarization direction may be processed for determining the amount of electric current 37.

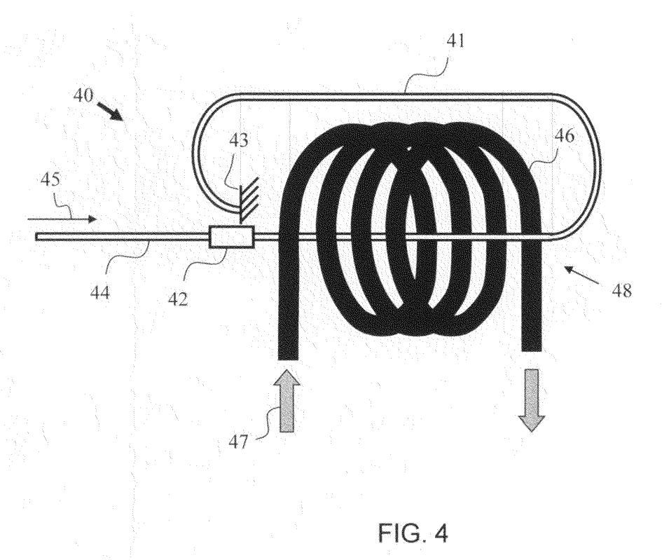

FIG. 4 is a demonstrative illustration of a sensor probe that may be used in a fiber-based current sensor according to yet another embodiment of the present invention. For example, sensor probe 40 may be similar to sensor probe 20 shown in FIG. 2, as a reflective-type sensor probe, in that sensor probe 40 may include a sensing fiber 41, placed inside a center hole or through-hole 48 of a spiral shape conductor 46. A first end of sensing fiber 46 may be connected to an input/output fiber 44 through a quarter-wave plate 42 and a second end of sensing fiber 46 may be terminated by a reflective mirror 43 or may be optically treated with an optical coating to have the effect of a mirror. An electric current 47 conveyed by conductor 46 may be detected and/or determined by detecting changes in polarization direction of an optical signal/light 45 launched into and reflected back from optical fiber 41. However, sensor probe 40 is different from sensor probe 20 in that the second end of sensing fiber 46 is rounded back to the first end and placed in a location substantially close to first end close to quarter-wave plate 42.

According to embodiment of the present invention, by virtue of the use of a “closed loop” fiber 41, a current sensor employing sensor probe 40 becomes further immune to external interferences, such as thunder or strong electromagnetic field. According to one embodiment, one coil or one loop of fiber 41 is sufficient to achieve the above immunity of sensor probe 40 to external electromagnetic interferences and/or noises. In fact, the less the number of coils of fiber is used, the more stable performance of the current sensor becomes.

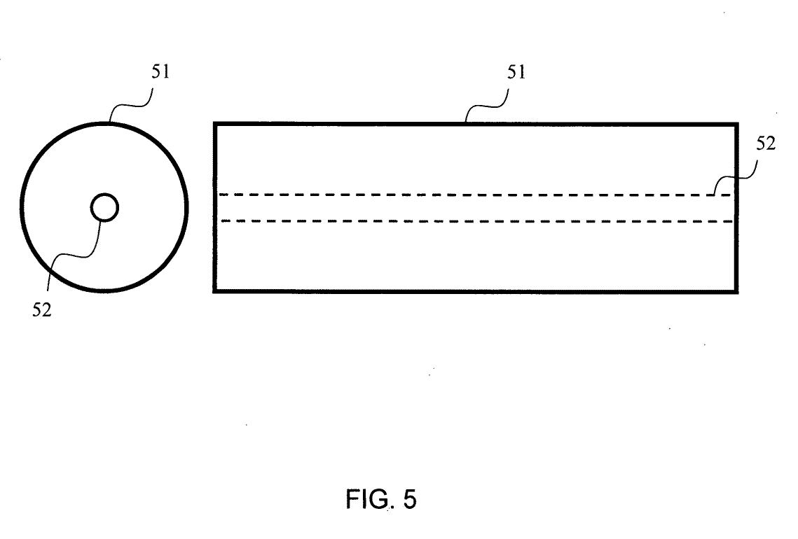

FIG. 5 is a demonstrative illustration of a method of manufacturing a sensor probe according to one embodiment of the present invention. For example, the method may include providing a bulky conductor 51 of, for example, aluminum or copper or any other conductive materials that is suitable for carrying large (up to several thousands amperes) electric current. In one embodiment, conductor 51 may be made of the same material as the conductors used in a conventional current sensor such as conductor 14 in FIG. 1A and FIG. 1B. Conductor 51 may be in a cylindrical form or may be machined to have a cylindrical form. Cylindrical conductor 51 may have a diameter between about 120 mm and about 180 mm and the diameter may be at least twice as big as a diameter of conductors used in a conventional current sensor such as conductor 14 (FIG. 1A).

Next, the method may machine a through-hole 52 in the center of cylindrical conductor 51. In one embodiment, through-hole 52 may be machined at a later stage after cylindrical conductor 51 is formed or machined into a spiral shape conductor. Through-hole 52 may have a diameter preferably slightly bigger that the size of a crystal tube which will be used in holding a sensing fiber inside through-hole 52, as being described below in more details. For example, through-hole 52 may have a diameter of about 20 mm or less, which may vary depending upon the size of the crystal tube to be used.

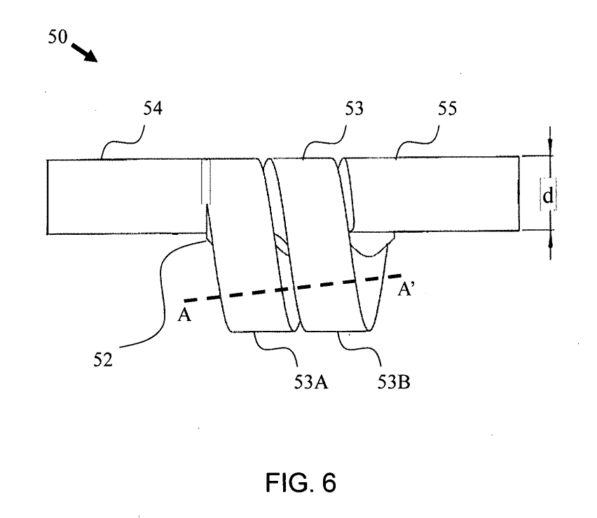

FIG. 6 is a demonstrative illustration of a method of manufacturing a sensor probe according to another embodiment of the present invention. The method may include machining cylindrical conductor 51 into a spiral shape form 53 with one or more coils, for example coil 53A and 53B. According to one embodiment, the distance between two adjacent coils is flexible and may only be limited by the overall size of sensor probe 50. Sensor probe 50 may also include port 54 and port 55 for the input and output of electric current. In one embodiment, input/output ports 54 and 55 may be machined out of cylindrical conductor 51. In another embodiment, input/output ports 54 and 55 may be made separately, preferably using the same material as conductor 51, and then be bonded together with spiral-shape formed conductor 53. Input/output ports 54 and 55 may have a diameter “d” around approximately 50 mm to 80 mm sufficient to support the large electric current (up to several thousands amperes) conveyed by the spiral shape conductor, slightly less than half of the diameter of cylindrical conductor 51, and a length approximately 10 mm to 50 mm. However, embodiments of the present invention are not limited in this aspect and other dimensions may be used as well. In one embodiment, a cross-sectional area of the coil made of the spiral shape conductor, taken in perpendicular to the direction of current flow along dashed line AA′ as shown in FIG. 6, may not be made smaller than a cross-sectional area of the input/output ports 54 and 55, assuming same type of materials being used. This way, spiral shape conductor 53 does not create extra heat due to high resistance caused by smaller cross-section when conveying the electric current inside thereof.

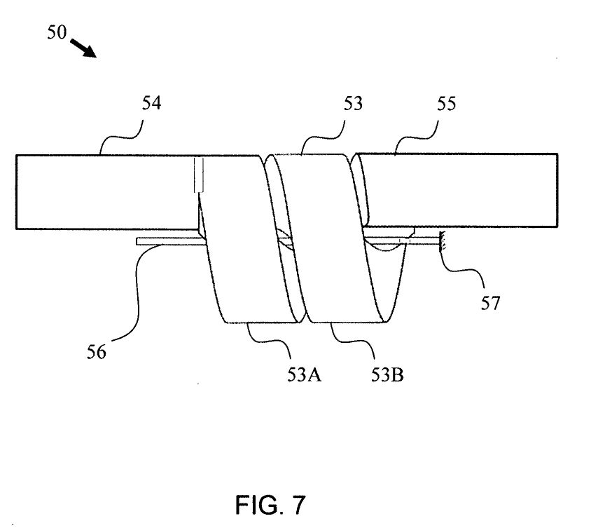

FIG. 7 is a demonstrative illustration of a method of manufacturing a sensor probe according to yet another embodiment of the present invention. Following the formation of spiral shape conductor 53 and through-hole 52 formed thereby, the method includes placing a relatively straight optical fiber 56 inside through-hole 52 of spiral shape conductor 53. The optical fiber 56 may be surrounded or covered by a protective cover which may be for example a crystal tube. The protective cover or protective tube may be affixed or firmly attached or fastened to spiral shape conductor 53 through, for example, one or more screws or other fastening elements to prevent moving. In FIG. 7, optical fiber 56 is terminated by a reflective mirror 57. However, embodiments of the present invention is not limited in this respect and both terminals of optical fiber 56 may be connected to quarter-wave plates (like in FIG. 3) or one of the terminal or port may be rounded back via outside of spiral shape conductor 53 (like in FIG. 4) to the other terminal to form a fiber coil, as being illustrated in FIGS. 2, 3, and 4.

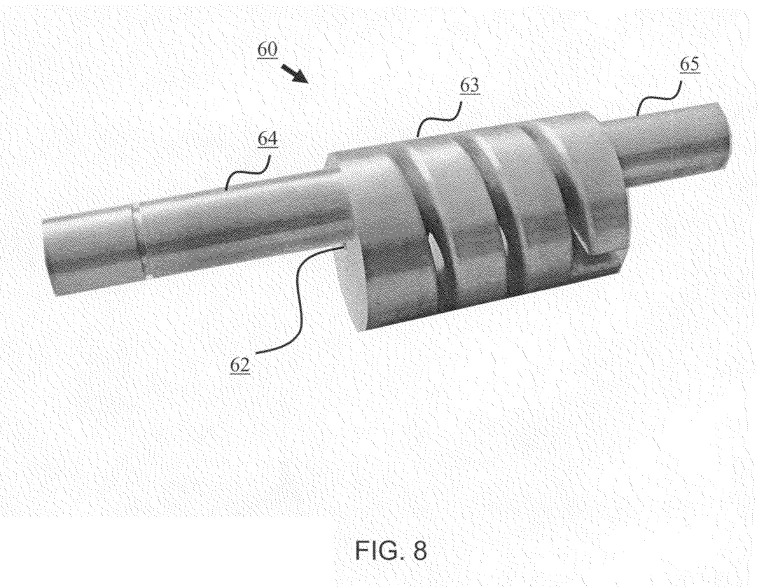

FIG. 8 is a picture of a prototype sensor probe, made in accordance with embodiment of the present invention, before a sensing fiber is installed in the through-hole. It is shown in the picture that sensor probe 60 has a spiral shape conductor 63 to which an input port 64 and an output port 65 are attached (machined out of a same piece of conductive material). Spiral shape conductor 63 surrounds a through-hole 62 in the center thereof. Inside through-hole 62, a sensing fiber will be installed or inserted and will be preferably protected by a tube, for example, a crystal tube (not shown) to prevent bend and/or cut. The crystal tube may be affixed to spiral shape conductor 63 through one or more screws or any other suitable fastening elements.

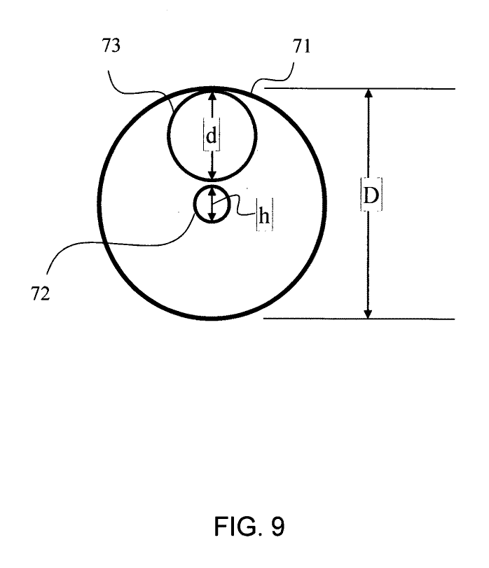

FIG. 9 is a demonstrative illustration of a cross-sectional review of a sensor probe made in accordance with one embodiment of the present invention. The spiral shape conductor 71 has, in perpendicular to the direction of through-hole 72, an outer diameter of D and an inner diameter h. The inner diameter h is the diameter of through-hole 72 wherein a sensing fiber may be placed. At the two ends of spiral shape conductor, there are input/output terminals 73 with a diameter d. The input/output terminals 73 may be formed anywhere in the cross-section of spiral shape conductor 71 (but away from through-hole 72), and may not be aligned with each other.

Embodiments of the present invention may not be limited in the above aspect in terms of method of manufacturing the sensor probe. Other methods may be used as well. For example, the spiral shape conductor may be made through casting using pre-made molds of desirable shapes. The probe head of spiral shape, with a sensing fiber placed in a center hole thereof, may be serially connected in a conductive path of electric current for which detection is desired.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the spirit of the invention.

What is claimed is:

1. A sensor probe for sensing electric current comprising:
an optical fiber; and
a spiral shape conductor having at least one coil and a through-hole in a center of said spiral shape conductor formed by said coil,
wherein said optical fiber is placed inside and along said through-hole of said spiral shape conductor.

2. The sensor probe of claim 1, further comprising a protective tube being placed inside said through-hole of said spiral shape conductor, wherein said optical fiber is placed inside said protective tube, thereby being protected by said protective tube.

3. The sensor probe of claim 2, wherein said protective tube is a crystal tube and is attached to said spiral shape conductor by one or more fastening elements, and said optical fiber inside said crystal tube is substantially straight along said through-hole.

4. The sensor probe of claim 1, wherein said spiral shape conductor has a first and a second terminal providing a conductive path from said first terminal to said second terminal for an electric current, and wherein an optical signal propagating inside said optical fiber is adapted to detect said electric current conveyed by said spiral shape conductor.

5. The sensor probe of claim 1, wherein said spiral shape conductor has a first and a second terminal and has between two to four coils between said first and second terminals.

6. The sensor probe of claim 5, wherein said first and second terminals have a diameter of at least 50 mm and cross-sections of said first and second terminals are sufficiently large to support conveying a current between about 1500 A and 3500 A.

7. The sensor probe of claim 6, wherein said coils have a cross-sectional area that is at least as big as that of said first and second terminals.

8. The sensor probe of claim 1, wherein a quarter-wave plate is connected in series inside said optical fiber at a first side of said spiral shape conductor, and said optical fiber is terminated by a reflective mirror at a second side of said spiral shape conductor.

9. The sensor probe of claim 1, wherein a quarter-wave plate is connected in series inside said optical fiber at a first side of said spiral shape conductor, and wherein said optical fiber is rounded back from a second side of said spiral shape conductor, via outside thereof, to said first side of said spiral shape conductor and is terminated by a reflective mirror at a location substantially close to said quarter-wave plate.

10. The sensor probe of claim 1, wherein a first and a second quarter-wave plate are connected in series inside said optical fiber at a first side and a second side of said spiral shape conductor.

11. The sensor probe of claim 1, wherein said spiral shape conductor is adapted to support an electric current flow of between about 1500 A and about 3500 A without generating substantial heat affecting the performance of said sensor probe.

12. A method of detecting electric current comprising:
launching an optical signal into an optical fiber, said optical fiber having a relatively straight section being placed inside a through-hole of a spiral shape conductor;
conveying an electric current through said spiral shape conductor;
detecting a rotation of polarization direction of said optical signal; and
determining an amount of the electric current from said rotation of polarization direction.

13. The method of claim 12, wherein said optical signal is launched into said optical fiber at a first end of said optical fiber, via a quarter-wave plate, further comprising applying a reflective mirror at a second end of said optical fiber in reflecting said optical signal back toward said first end of said optical fiber.

14. The method of claim 12, wherein conveying said electric current comprises causing said electric current of between about 1500 A and 3500 A to pass along said spiral shape conductor without causing substantial heat being generated inside said spiral shape conductor.

15. A method of making sensor probe comprising:
providing a bulky cylindrical conductor;
machining a through-hole at a center of said cylindrical conductor;
machining said cylindrical conductor into a spiral shape, said spiral shape surrounding said through-hole; and
positioning an optical fiber substantially straight inside said through-hole.

16. The method of claim 15, wherein positioning said optical fiber inside said through-hole further comprises:
placing said optical fiber inside a protective tube;
positioning said protective tube inside said through-hole; and
fastening said protective tube to said spiral shape conductor by one or more fastening elements.

17. The method of claim 16, wherein said protective tube is a crystal tube being adapted to hold said optical fiber in a substantial straight manner.

18. The method of claim 15, further comprising:
connecting a quarter-wave plate to a first end of said optical fiber, said first end of said optical fiber being at a first side of said spiral shape conductor; and
terminating a second end of said optical fiber with a reflective mirror, said second end of said optical fiber being at a second side of said spiral shape conductor.

19. The method of claim 18, further comprising rounding said second end of said optical fiber through outside of said spiral shape conductor back to said first side of said spiral shape conductor and placing at substantially close to said first end of said optical fiber.

20. The method of claim 15, further comprising connecting a quarter-wave plate to a first and a second end of said optical fiber, at a first side and a second side of said spiral shape conductor, respectively.
